(19) United States
(12) Patent Application Publication
(10) Pub. No.: US 2015/0168922 A1
(43) Pub. Date: Jun. 18, 2015

(54) SOLAR CLOCK

(71) Applicant: SEIKO EPSON CORPORATION, Tokyo (JP)

(72) Inventors: Kunio WANIKAWA, Matsumoto-shi (JP); Masahiro FURUSAWA, Chino-shi (JP)

(21) Appl. No.: 14/561,721

(22) Filed: Dec. 5, 2014

(30) Foreign Application Priority Data
Dec. 16, 2013 (JP) 2013-259586

(51) Int. Cl. G04G 19/00; H01L 31/042

(52) U.S. Cl. CPC G04G 19/00; H01L 31/042

(57) ABSTRACT

A solar clock includes a connector member having an adhesive layer formed on one side of a flexible base material, a plurality of solar cells bonded to the adhesive layer, and a wire formed on one or both of a front surface and a rear surface of the connector member and electrically connecting the plurality of solar cells.

### CROSS-REFERENCE TO RELATED APPLICATION

This application claims a priority to Japanese Patent Application No. 2013-259586 filed on Dec. 16, 2013 which is hereby expressly incorporated by reference in its entirety.

### BACKGROUND

1. Technical Field

Several aspects of the present invention relate to a solar clock.

2. Related Art

Solar clocks have been widespread because battery replacement is unnecessary and their mechanisms are simple. For solar cells for solar clocks, amorphous silicon semiconductors that exhibit higher power generation efficiency even under indoor light are mainly used.

Patent Document 1 (JP-A-10-39057) discloses a technology, in a solar cell having a circular shape and including a plurality of photoelectric conversion elements having sector shapes, the respective photoelectric conversion elements series-connected by electrodes, of forming the plurality of photoelectric conversion elements having the sector shapes by cutting a photoelectric conversion layer formed on a substrate of a resin film by laser scribing.

In the case of the technology disclosed in Patent Document 1, for electric insulation of the respective photoelectric conversion elements, open grooves reaching the substrate are formed by laser. When the open grooves are formed, if the lower electrodes in contact with the substrate are not divided, short circuit easily occurs between the photoelectric conversion elements. Further, when the open grooves are formed to the deeper parts of the substrate, the substrate may be damaged and necessary strength may not be maintained. There are problems that steps necessary for processing of photoelectric conversion elements are larger in number and complex, an expensive processing device is required, and the throughput of production is lower. Further, a region to be a single solar cell module is defined on the substrate in a predetermined circular shape, then, various kinds of processing is performed thereon, and thereby, when a defect occurs in one location in the region to be the single solar cell module, all of the members within the region are wasted.

### SUMMARY

An advantage of some aspects of the invention is to provide a solar clock including a solar cell module in which a structure having a plurality of series-connected solar cells may be manufactured at lower cost.

A solar clock according to an aspect of the invention includes a connector member having an adhesive layer formed on one side of a flexible base material, a plurality of solar cells bonded to the adhesive layer, and a wire formed on one or both of a front surface and a rear surface of the connector member and electrically connecting the plurality of solar cells.

According to the aspect, the adhesive layer that bonds and integrates the plurality of solar cells and the wire that electrically connects the plurality of solar cells are aggregated in the connector member principally including one flexible base material, and thereby, the number of parts may be reduced, the number of steps with the conducting operation may be reduced, and consequently, the cost may be reduced.

In the solar clock described above, it is preferable that the adhesive layer is bonded to a light reception side of the solar cells, and the flexible base material has insulation properties and transparency.

According to this configuration, protection of the light reception side of the solar cells may be realized by bonding of the connector member and the connector member also serves as a protective film at the light reception side. Thereby, the material and the number of steps for forming the protective film may be reduced, and consequently, the cost may be reduced.

In the solar clock described above, it is preferable that the plurality of solar cells respectively have electrodes on front surfaces and rear surfaces, the plurality of solar cells are electrically series-connected, in a location where an electrode on the rear side in a first solar cell and an electrode on the front side in a second solar cell of the plurality of solar cells are series-connected, an intermediate part front-rear connection region provided as a part of the flexible base material connects the rear side in the first solar cell and the front side in the second solar cell, and a wire that electrically connects the electrode on the rear side in the first solar cell and the electrode on the front side in the second solar cell is provided in the intermediate part front-rear connection region.

According to this configuration, the wire that electrically connects the electrode on the rear side in the first solar cell and the electrode on the front side in the second solar cell is provided in the intermediate part front-rear connection region as a part of the flexible base material, and thereby, in a state in which the plurality of solar cells are integrated by the connector member, the series connection between the solar cells may be easily realized only by moving the intermediate part front-rear connection region in the connector member.

In the solar clock described above, it is preferable that the plurality of solar cells respectively have electrodes on front surfaces and rear surfaces, the plurality of solar cells are electrically series-connected, the plurality of solar cells have a first end solar cell with the electrode on the front side as output and a second end solar cell with the electrode on the rear side as output on both ends of the series connection, an output terminal to which the electrode on the front side of the first end solar cell is connected is provided on the rear side of one solar cell of the first end solar cell and the second end solar cell, the output terminal is electrically insulated from the electrode on the rear side of the solar cell through intervention of the flexible base material, an end part front-rear connection region provided as apart of the flexible base material connects the front side of the first end solar cell and the rear side of the solar cell on which the output terminal is provided, and a wire that electrically connects the electrode on the front side of the first end solar cell and the output terminal is provided in the end part front-rear connection region.

According to this configuration, the wire that electrically connects the electrode on the front side of the first end solar cell and the output terminal provided on the rear side of the solar cell is provided in the end part front-rear connection region as a part of the flexible base material, and thereby, in a state in which the plurality of solar cells are integrated by the connector member, the conduction connection between the electrode on the front side and the output terminal may be easily realized only by moving the end part front-rear connection region in the connector member. In the case where the number of solar cells is three or more, the output terminal may be provided on the rear side of the solar cell not located on the ends of the series connection, however, the output terminal is provided on the rear side of the solar cell on one of both ends of the series connection, and thereby, the length of the wire may be made shorter, the space and the cost of materials may be saved, and the operability may be improved.

In the solar clock described above, it is preferable that the electrodes of the plurality of solar cells and the wire are connected using an anisotropic conductive adhesive agent.

According to this configuration, the electrodes of the plurality of solar cells and the wire may be fixed by bonding and the electrodes of the plurality of solar cells and the wire may be selectively conducted and electrically connected at the same time, and thereby, operability and conduction reliability are advantageous.

A method of connecting solar cells according to another aspect of the invention includes: preparing a connector member having an adhesive layer formed on one side of a flexible base material and a wire formed on one or both of a front surface and a rear surface of the flexible base material, positioning a plurality of solar cells to bond to the adhesive layer, and electrically connecting the plurality of solar cells by thermal compression bonding via the wire.

According to the aspect, the adhesive layer that bonds and integrates the plurality of solar cells and the wire that electrically connects the plurality of solar cells are aggregated in the connector member principally including one flexible base material, and thereby, the number of parts may be reduced and the number of steps with the conducting operation may be reduced at manufacturing of a solar cell module for solar clock, and consequently, the cost may be reduced.

### BRIEF DESCRIPTION OF THE DRAWINGS

The invention will be described with reference to the accompanying drawings, wherein like numbers reference like elements.

FIG. 1 is a plan view showing an example with respect to a schematic configuration of a solar clock.

FIG. 2A is a plan view showing an arrangement of solar cells and FIG. 2B is a plan view showing a solar cell module with respect to the solar cell module of the first embodiment.

FIG. 3 is a sectional view showing a sectional structure of a part A-B in FIG. 2B.

FIG. 4 is a circuit diagram of the solar cell module of the first embodiment.

FIGS. 5A and 5B are sectional views for exemplification of wire connection structures.

FIG. 6 is a plan view for exemplification of a wire connection structure.

FIG. 7 is a perspective view showing an example of a structure for connection between a movement unit and the solar cell module.

FIG. 8A is a plan view showing an arrangement of solar cells and FIG. 8B is a plan view showing a solar cell module with respect to the solar cell module of the second embodiment.

FIG. 9 is a circuit diagram of the solar cell module of the second embodiment.

FIGS. 10A and 10B are sectional views for exemplification of wire connection structures.

### DESCRIPTION OF EXEMPLARY EMBODIMENTS

As below, solar clocks and solar cell modules according to embodiments of the invention will be explained with reference to the drawings.

Note that the scope of the invention is not limited to the following embodiments, but may be arbitrarily changed within the technical scope of the invention. Further, in the following drawings, scales, numbers, etc. in respective structures may be differentiated from those in real structures for making the respective configurations understandable.

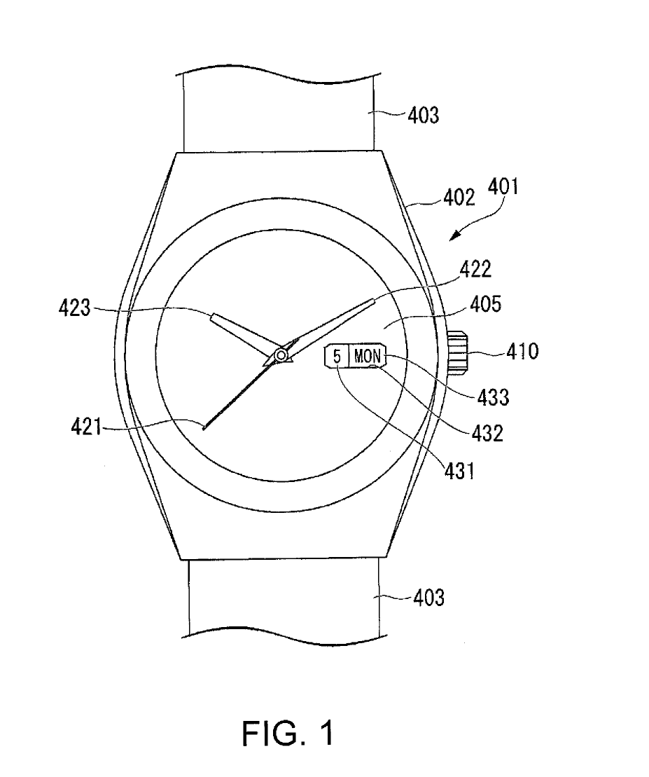

FIG. 1 shows an example of a watch (wrist watch) as a schematic configuration of a solar clock. The watch 401 includes a watch case 402 and a pair of bands 403, 403 coupled to the watch case 402. The watch case 402 is formed using a metal material such as stainless steel, a plastic resin, or the like. On the outer surface of the watch case 402, a winder 410 is provided as an operator. Operations of setting the watch etc., on/off of the operations, and the like may be performed by pressing, pulling, rotating the winder 410.

The watch case 402 contains a face 405, a second hand 421, a minute hand 422, an hour hand 423, a date wheel 431, etc. The second hand 421, the minute hand 422, and the hour hand 423 are coaxially provided. The date wheel 431 indicates a date through a date window 432 formed in the face 405. A day wheel 433 displaying a day of the week may be provided in the date window 432.

The face 405 is a flat plate having indication of characters, scales, etc. for time display (not shown). Under the face 405, a solar cell module (not shown) is provided. The face 405 for solar clock has translucency. The light transmittance of the face 405 is e.g., 20%. The solar cell module supplies power to drive parts (not shown) that drive indication means of the second hand 421, the minute hand 422, the hour hand 423, the date wheel 431, etc. Further, surplus power charges a secondary cell (not shown). The drive parts may be supplied with power from the secondary cell when the amount of generated power of the solar cell module is insufficient. The solar clock is often used outdoors, and about two to four solar cells are generally series-connected in the solar cell module.

### First Embodiment

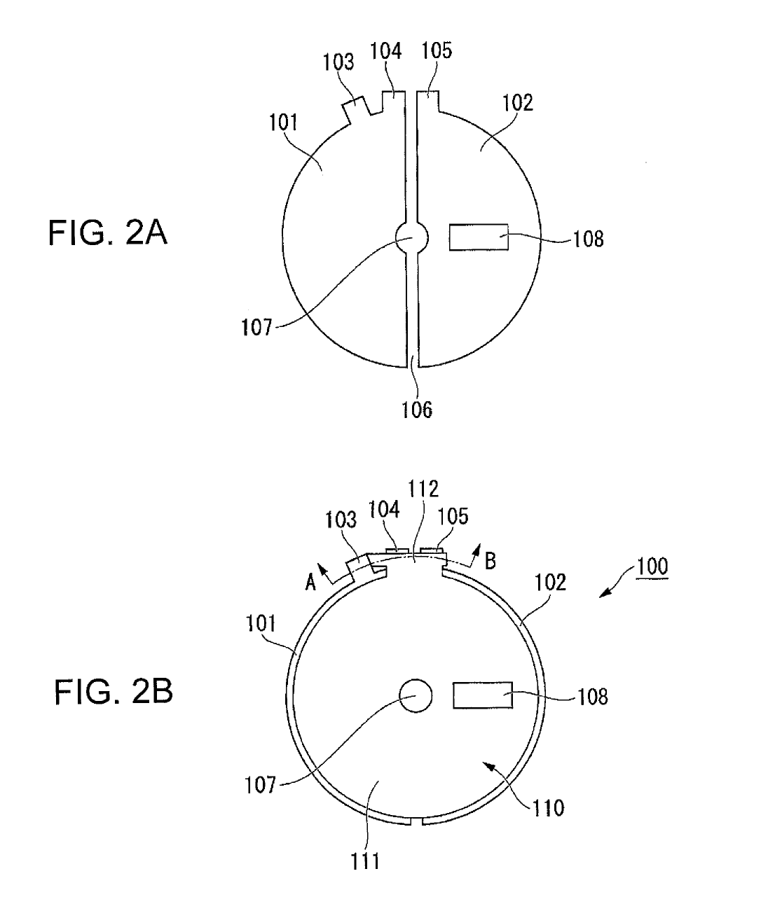

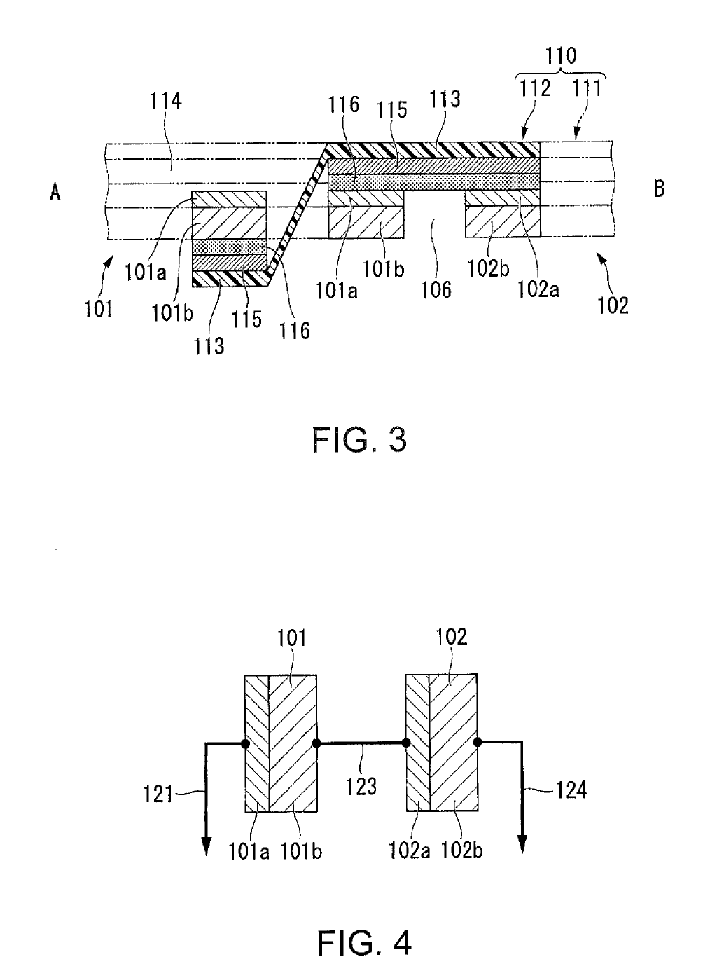

FIG. 2B shows a solar cell module 100 of the first embodiment. Further, FIG. 2A shows an arrangement of solar cells 101, 102 in the solar cell module 100. FIG. 3 shows a sectional structure of a part A-B in FIG. 2B.

In the embodiment, the solar cell module 100 has a nearly circular shape like the above described face 405. The solar cells 101, 102 are photoelectric conversion type power generation elements that can convert light energy into electric energy (also called solar cells). Lights as sources of light energy include many kinds of lights such as sunlight, indoor light, artificial illumination light, visible light, infrared light, and ultraviolet light.

As shown in FIG. 2A, the two solar cells 101, 102 have nearly semi-circular shapes. A linear gap 106 is formed between the solar cells 101, 102. As shown in FIG. 2B, the independent solar cells 101, 102 are combined on a plane using a connector member 110 to form a nearly circular shape as a whole. It is preferable that the width of the gap 106 is wide to suppress contact between the solar cells 101, 102 and narrow to suppress bending of a flexible base material 113.

At the center of the solar cell module 100, a hand hole 107 for placing the watch hands is provided. Further, in a position corresponding to the date window 432 (see FIG. 1) of the watch 401, a date window 108 is provided. The hand hole 107 and the date window 108 are through holes penetrating the solar cells 101, 102 and the connector member 110. In the example of FIG. 2A, the hand hole 107 is formed as a cutout in a circular arc shape at both sides in the width direction of the gap 106 with respect to both solar cells 101, 102. Further, the date window 108 is formed in the solar cell 102.

The connector member 110 includes a cell coupling region 111 that couples the solar cells 101, 102, and a front-rear connection region 112 that connects the front side and the rear side in terminal parts 103, 104, 105 of the solar cells 101, 102. As shown in FIG. 3, the cell coupling region 111 of the connector member 110 includes the flexible base material 113 and an adhesive layer 114. In the embodiment, the adhesive layer 114 is bonded to positive electrodes 101a, 102a at the light reception side of the solar cells 101, 102.

The flexible base material 113 is electrical insulation properties, and thereby, if directly bonded to the positive electrodes 101a, 102a, does not cause short circuit between the electrodes. Further, the flexible base material 113 is transparent, and thereby, sufficient light reception of the solar cells 101, 102 may be allowed. It is only necessary that the flexible base material 113 has translucency not to hinder photovoltaic generation of the solar cells. It is preferable that the flexible base material 113 has transparency through which the shapes of the solar cells 101, 102 can be visually recognized, and thereby, the positioning operation of the solar cells 101, 102 is easier. The light transmittance of the flexible base material is equal to or more than 20%, for example, and may be equal to or more than 50%.

Specific examples of the flexible base material 113 include transparent film base materials of a polyester resin, a polycarbonate resin, an acrylic resin, and a polyvinyl alcohol resin, or the like. For example, polyethylene terephthalate (PET) as a kind of polyester resin is preferable because it is inexpensive and advantageous in mechanical and optical characteristics. The bending elasticity of the flexible base material 113 is smaller than the bending elasticity of the solar cells 101, 102.

The adhesive layer 114 is formed on one side of the flexible base material 113. The adhesive layer 114 contains an adhesive agent attachable by pressing at room temperature (pressure sensitive adhesive), and thereby, the solar cells 101, 102 may be easily bonded and fixed even by hand. It is preferable that the adhesive agent has re-detachability to be detachable after attachment because, if the bonding position is erroneous, the agent may be detached without damaging the solar cells 101, 102. Further, with the adhesive agent that can be re-attached after detachment, the connector member 110 is re-attachable and operability is improved. It is preferable that the adhesive agent is harder to alter the electrode material of the solar cells 101, 102 and has the equal insulation property and translucency or transparency to those of the flexible base material 113. As methods of forming the adhesive layer 114 on one side of flexible base material 113 include a method of attaching a double-faced adhesive tape on a film base material by roll laminating and a method of applying a liquid adhesive agent on one side of a film base material, and then, curing the adhesive agent layer.

The solar cells 101, 102 have the positive electrodes 101a, 102a as the electrodes on the front side (light reception side) and negative electrodes 101b, 102b as electrodes on the rear side. The positive electrodes 101a, 102a are transparent conducting layers of ITO (indium tin oxide) or the like, and the negative electrodes 101b, 102b are opaque metal layers of stainless steel (e.g., SUS), for example.

The two solar cells 101, 102 include the solar cell 101 having the two terminal parts 103, 104 and the solar cell 102 having the one terminal part 105. The processing process of the solar cells having the terminal parts may include a step of molding the solar cells from a large-area solar cell panel in predetermined shapes containing the circular parts and the terminal parts, and a step of forming the terminals using a technique including screen printing of e.g., conductive paste in the terminal parts.

The molding of the planar shapes of the solar cells may be performed by appropriately selecting etching, mechanical cutting, laser processing, or the like depending on the materials. When the solar cells are processed from the solar cell panel, the regions to be the respective solar cells may be set in arbitrary orientations on the solar cell panel. Compared to the case where solar cells are processed in nearly circular shapes with room for dimensions of the faces in related art, the embodiment causes less processing loss. Even when a processing defect occurs in one location, only one solar cell corresponding to the half of the solar cell for watch is defective, and waste may be reduced.

The power generation structure (not shown) stacked between the positive electrodes and the negative electrodes in the solar cells is not particularly limited. An example includes a structure in which an SUS substrate as the electrode on the rear side, an aluminum layer (Al layer), a zinc oxide layer (ZnO layer), a power generation layer, and an ITO layer as the electrode on the front side are sequentially stacked. The aluminum layer has a surface with concavities and convexities and scatters and reflects light transmitted through the power generation layer of the lights entering from the ITO layer. The zinc oxide layer adjusts the optical refraction index between the power generation layer and the aluminum layer.

It is preferable that the power generation layer is a multi-layered structure (multi-junction structure) multi-junction power generation layer. Three of the power generation layers respectively absorb lights having different wavelengths, and thereby, power generation efficiency may be improved. As the power generation layer, a semiconductor layer such as an amorphous silicon germanium layer (a-SiGe layer) or an amorphous silicon layer (a-Si layer) is preferable because they have good power generation efficiency even under light with lower illuminance like indoor light.

A power generation structure at lower cost includes a structure in which an amorphous silicon layer (power generation layer) is stacked on an SUS substrate (negative electrode) and an ITO layer (positive electrode) is further stacked on the amorphous silicon layer.

The surface of the transparent conducting layer like the ITO layer is susceptible to scratch and static electricity, and a protective film may be provided on the transparent conducting layer by coating of a transparent insulating resin using screen printing. In the embodiment, the coating of the protective film may be omitted and the adhesive layer 114 of the connector member 110 may be directly bonded onto the transparent conducting layer. In this case, the transparent connector member (specifically, the cell coupling region) may also serve as the protective film at the light reception side, and the material and the number of steps for forming the protective film may be reduced.

The positive electrodes 101a, 102a and the negative electrodes 101b, 102b of the solar cells 101, 102 are respectively formed to the terminal parts 103, 104, 105. For convenience of explanation, the terminal part 103 in the solar cell 101 at the side farther from the solar cell 102 is distinguished as a first terminal part 103, the terminal part 104 in the solar cell 101 at the side nearer the solar cell 102 is distinguished as a second terminal part 104, and the terminal part 105 of the solar cell 102 is distinguished as a third terminal part 105.

As shown in FIG. 3, the front-rear connection region 112 of the connector member 110 has the flexible base material 113 continuing from the cell coupling region 111, and connects the rear side of the first terminal part 103 and the front sides of the second terminal part 104 and the third terminal part 105. The front-rear connection region 112 is flexible because of the flexible base material 113 and easily passed through between the first terminal part 103 and the second terminal part 104. The front-rear connection region 112 has a wiring layer 115 and an anisotropic conductive adhesive layer 116 stacked on the front surface or the rear surface of the flexible base material 113. A method of forming the wiring layer 115 includes a method of screen printing conductive paste such as silver paste and a method of forming a conducting layer in a predetermined pattern using evaporation, plating, etching, or the like.

The electrodes (positive electrodes 101a, 102a and negative electrode 101b) of the solar cells 101, 102 and the wiring layer 115 may be electrically connected by the anisotropic conductive adhesive layer 116 by heating and pressurizing the parts requiring conduction. An anisotropic conductive adhesive forming the anisotropic conductive adhesive layer 116 includes, e.g., anisotropic conductive paste (ACP) having a composition in which conductive particles of metal particles or the like are formulated in a dispersed state in a binder of resin or the like and an anisotropic conductive sheet that can be heat-sealed by hot melt. In the locations not requiring conduction, even when the anisotropic conductive adhesive layer 116 is stacked, the conductive particles in the binder are not in contact and the electrodes and the wires are not conducted. In the heated and pressurized locations, the thermoplastic anisotropic conductive adhesive may bond and fix the electrodes and the wires and conduct between the electrodes and the wires at the same time. This is because the binder flows due to heating and pressurization and the conductive particles come into contact with each other and the conductive particles come into contact with the electrodes and the wires. It is preferable that the anisotropic conductive adhesive is a mixture containing a pressure-sensitive adhesive that exhibits adhesion by pressure sensitivity even in the room temperature and a heat-sensitive adhesive that exhibits adhesion by heating because the locations not heated and not conducted can be bonded and fixed, and further, the bonding strength in the locations conducted by heating rises.

FIG. 4 shows a schematic circuit diagram of the solar cell module 100. The positive electrode 101a of the solar cell 101 is connected to a positive output terminal 121. The negative electrode 101b of the solar cell 101 is connected to the positive electrode 102a of the solar cell 102 via a wire 123. The negative electrode 102b of the solar cell 102 is connected to a negative output terminal 124. Thereby, the two solar cells 101, 102 are electrically series-connected between the positive output terminal 121 and the negative output terminal 124, and the output voltage may be increased.

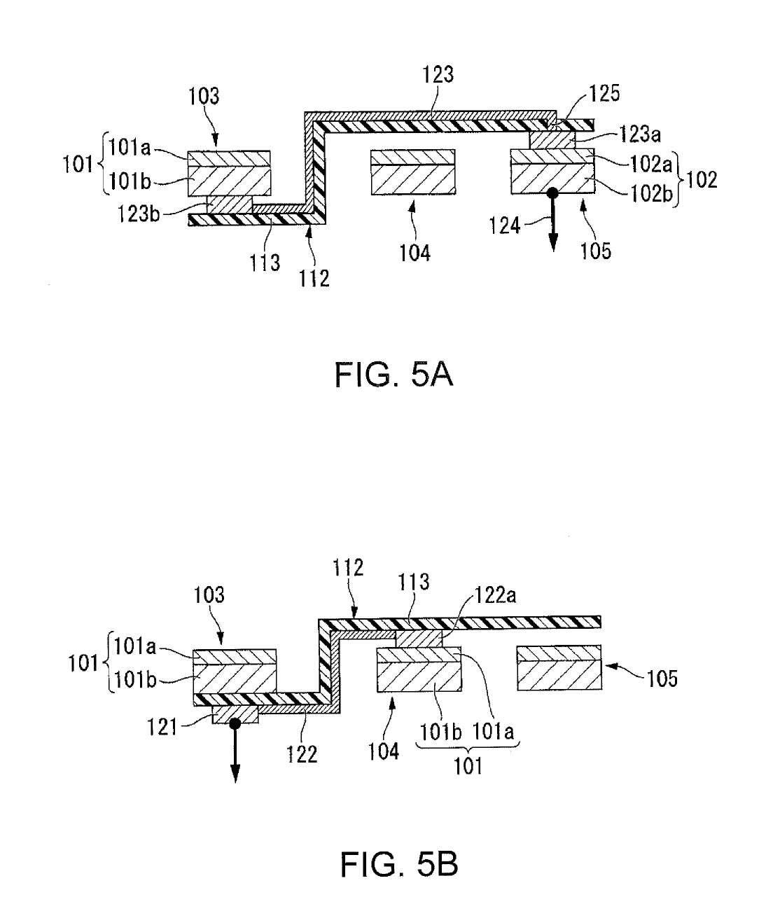

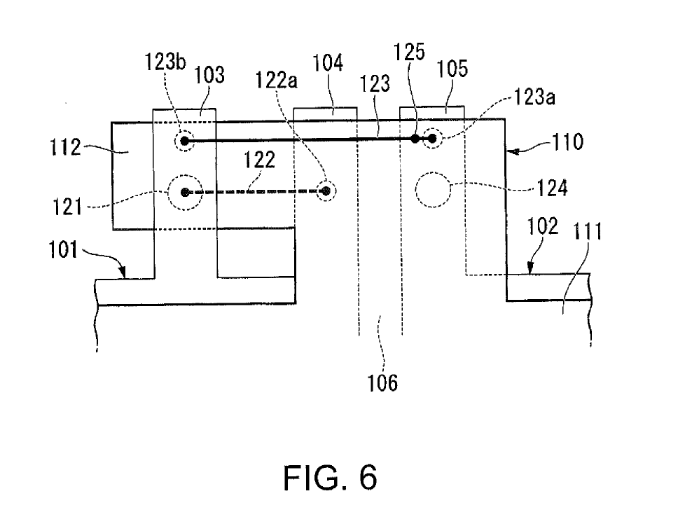

Connection structures of wires are exemplified in sectional views in FIGS. 5A and 5B and a plan view in FIG. 6.

In the first terminal part 103, a terminal 123b on the negative electrode 101b of the solar cell 101 is connected to the wire 123 and the positive output terminal 121 on the flexible base material 113 is connected to a wire 122. The positive output terminal 121 and the negative electrode 101b of the solar cell 101 are electrically insulated by the insulating flexible base material 113.

In the second terminal part 104, a terminal 122a on the positive electrode 101a of the solar cell 101 is connected to the wire 122.

In the third terminal part 105, the terminal 123a on the positive electrode 102a of the solar cell 102 is connected to the wire 123 and the negative electrode 102b of the solar cell 102 is connected to the negative output terminal 124.

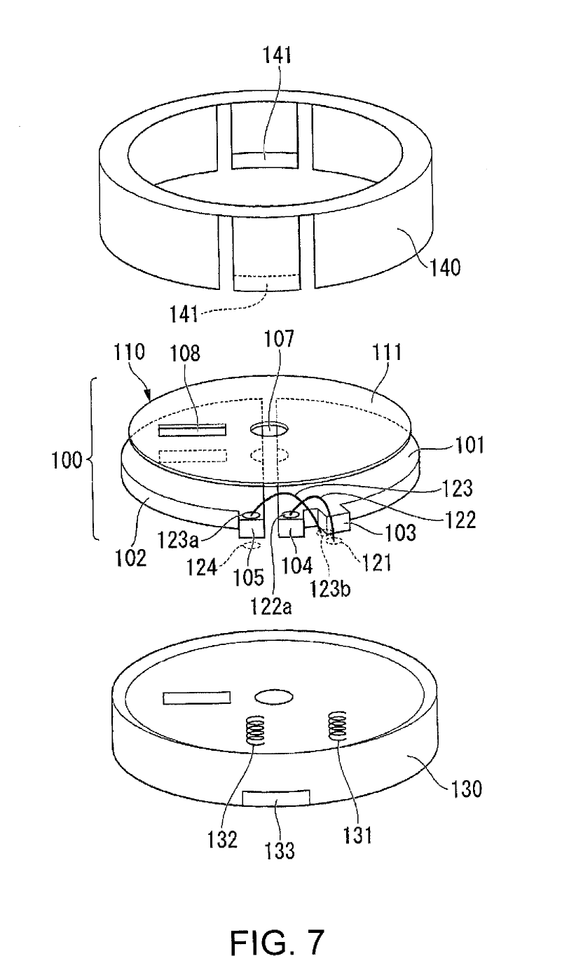

The positive output terminal 121 and the negative output terminal 124 are provided on the rear sides of the solar cells 101, 102, and thereby, terminals for extracting the generated power may be provided on the rear side of the solar cell module 100. As will be described later, this is preferable when input terminals are provided on the same surface of a movement unit 130 (see FIG. 7) and connected to the output terminals of the solar cell module because conduction may be obtained by placing the solar cell module on the input terminals and pressing it.

The wire 123 that series-connects the solar cells 101, 102 and the terminals 123a, 123b on both ends may be formed as a wiring layer on the front side of the flexible base material 113 in the front-rear connection region 112. The terminal 123b is located on the front side of the flexible base material 113 and the terminal 123a is located on the rear side of the flexible base material 113, and accordingly, the wire 123 passes a through hole 125 penetrating the flexible base material 113.

The wire 122 connected to the positive electrode 101a of the solar cell 101 and the terminal 122a and the positive output terminal 121 may be formed as a wiring layer on the rear side of the flexible base material 113 in the front-rear connection region 112.

As described above, when the wires are formed as the wiring layer on the front surface or the rear surface of the connector member 110, the wires are integrated with the flexible base material. Thereby, an operation of individually positioning the wires becomes unnecessary and they may be positioned only by aligning predetermined locations of the front-rear connection region 112 with the positions of the electrodes. It is preferable that the flexible base material is transparent because the positions of the wires may be visually aligned with the positions of the electrodes. The negative output terminal 124 may be formed using conductive paste, plating, or the like. A part of the negative electrode 102b of the solar cell 102 may be used as the negative output terminal 124 without special processing.

It is preferable that the assembly procedure of the solar cell module 100 is as follows: the cell coupling region 111 is bonded to a part inner than the outer peripheral part of the nearly circular shape of the solar cells 101, 102, and then, the front-rear connection region 112 is bonded to the terminal parts 103, 104, 105 and the connecting operation between the electrodes and the wires is performed. The connector member 110 has flexibility as a whole, accordingly, the degree of bending of the flexible base material 113 is changed at the positioning of the electrodes and the wires, and thereby, displacement may be absorbed by the flexible base material 113.

The terminal parts 103, 104, 105 may be provided outside of the region where light can be received through the face. The terminal parts 103, 104, 105 project from the outer peripheral part of the nearly circular shape of the solar cells 101, 102, and bonding of the terminal parts 103, 104, 105 to the front-rear connection region 112 is easy. The connector member 110 may be bonded using pressure sensitivity, and thereby, may be bonded and fixed at the room temperature after positioning with sufficient accuracy by hand. The solar cells 101, 102 are integrated by the connector member 110, and thereby, both alignment and temporary fixation may be performed even by hand and operability is improved. Further, the electrodes of the solar cells and the wires are bonded by thermal compression using a thermal compression unit and the anisotropic conductive adhesive is conducted, and thereby, fixation becomes more reliable.

According to the embodiment, the adhesive layer 114 for bonding and integrating the plurality of solar cells 101, 102 and the wires 122, 123 used for electrical connection are integrated in the connector member 110 including the flexible base material 113 as a principal member, and thus, the number of parts may be reduced, the number of steps with the conducting operation may be reduced, and consequently, the cost may be reduced. The solar cells 101, 102 may be positioned with each other only by alignment and attachment of the connector member 110, and thus, the complex temporal fixation step may be omitted and the electrodes and the wires may be directly bonded by thermal compression.

In the embodiment, when the solar cell 101 is referred to as “first solar cell” and the solar cell 102 is referred to as “second solar cell”, the wire 123 is a wire that electrically connects the electrode on the rear side in the first solar cell and the electrode on the front side in the second solar cell. Further, when the solar cell 101 is referred to as “first end solar cell” and the solar cell 102 is referred to as “second end solar cell”, the positive output terminal 121 is an output terminal to which the electrode on the front side of the first end solar cell is connected and the wire 122 is a wire that electrically connects the electrode and the output terminal on the front side in the first solar cell. That is, the front-rear connection region 112 of the embodiment serves as both an intermediate part front-rear connection region and an end part front-rear connection region.

FIG. 7 shows an example of a structure of connecting the movement unit 130 and the solar cell module 100. In FIG. 7, in order to show the connection structure in the terminal parts 103, 104, 105 of the solar cell module 100, the connector member 110 is represented to float from the solar cells 101, 102 and the illustration of the flexible base material in the front-rear connection region 112 is omitted.

The movement unit 130 includes the drive parts (not shown) that drive the hands, the date wheel, etc. of the watch and a secondary cell (not shown) charged by surplus power. On the front surface of the movement unit 130, a positive spring electrode 131 and a negative spring electrode 132 are provided as input terminals that supply power generated in the solar cell module 100 to a circuit for inputting the power to the drive parts and the secondary cell. When the solar cell module 100 is placed on the front surface of the movement unit 130, the positive spring electrode 131 and the positive output terminal 121 are connected and the negative spring electrode 132 and the negative output terminal 124 are connected.

A pressing ring 140 has locking claws 141 engaged with engagement concavities 133 on the side surface of the movement unit 130. The pressing ring 140 is assembled in the movement unit 130, and thereby, the solar cell module 100 is held between the pressing ring 140 and the movement unit 130. The locking claws 141 shown in FIG. 7 are provided in two locations opposed in the outer circumferential (circumferential) direction of the pressing ring 140, however, may be provided in three or more locations. The pressing ring and the movement unit may be coupled in one location using a hinge and may be made detachable in the other location using a locking claw.

When light is applied from the face side, the solar cell module 100 mounted on the wrist watch is irradiated with light via the face having translucency. Thereby, the power generated in the solar cells 101, 102 is supplied to the movement unit 130. In the movement unit 130, the drive parts are driven by the supplied power and the secondary cell is charged. According to the connection structure of the embodiment, it is confirmed that power may be supplied from the solar cells 101, 102 to the movement unit 130 without loss.

According to the embodiment, the amorphous silicon solar cell is used, and thereby, even when the two solar cells 101, 102 are series-connected, a sufficient voltage may be obtained. Therefore, according to the solar clock of the embodiment, a higher drive voltage may be obtained with the solar cell module 100. Thus, a highly reliable solar clock that can be driven by stable power may be provided at lower cost.

### Second Embodiment

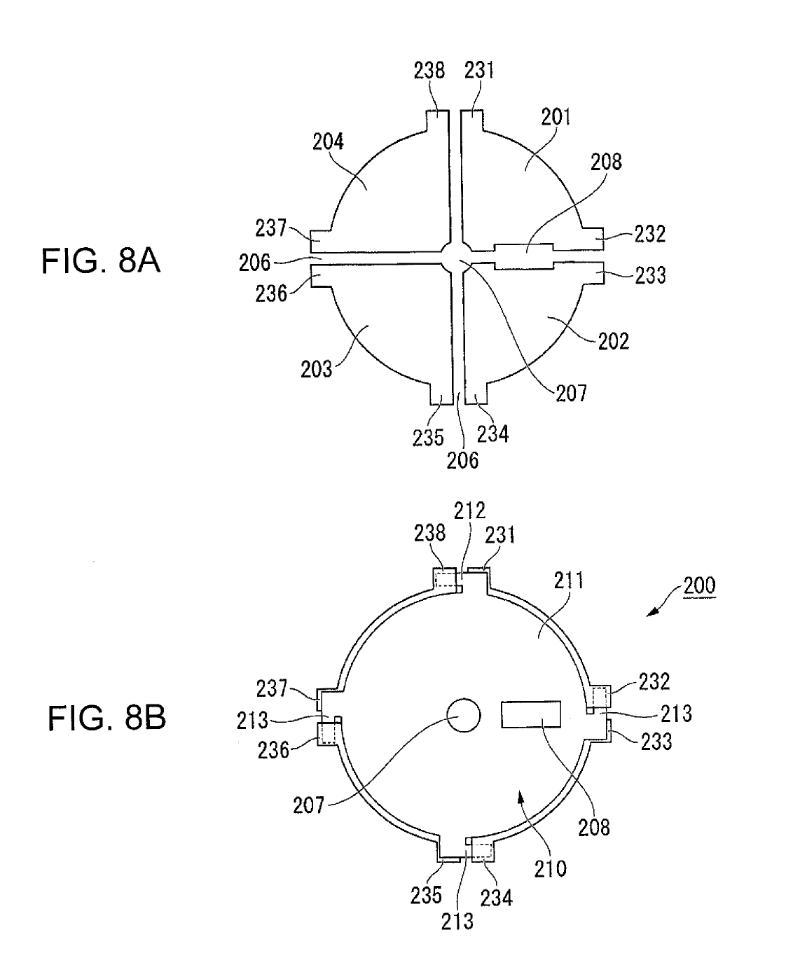

FIG. 8B shows a solar cell module 200 of the second embodiment. Further, FIG. 8A shows an arrangement of solar cells 201, 202, 203, 204 in the solar cell module 200. The configuration of the solar cell module 200 of the embodiment has a lot in common with that of the first embodiment, and the differences will be principally explained.

As shown in FIG. 8A, the four solar cells 201 to 204 have nearly sector shapes. Linear gaps 206 are formed between the solar cells 201 to 204. As shown in FIG. 8B, the independent solar cells 201 to 204 are combined on a plane using a connector member 210 to form a nearly circular shape as a whole. It is preferable that the width of the gaps 206 is wide to suppress contact between the solar cells 201 to 204 and narrow to suppress bending of a flexible base material in the connector member 210.

Like the gap 106, the hand hole 107, and the date window 108 in the solar cell module 100 of the first embodiment, the gaps 206, a hand hole 207, and a date window 208 are provided in the solar cell module 200. In response to the solar cell module 200 having the four solar cells 201 to 204, the gaps 206 form a cross shape. The date window 208 is formed as a cutout with respect to the solar cells 201, 202 at both sides in the width direction of the gap 206 between the solar cells 201, 202.

The connector member 210 includes a cell coupling region 211 that couples the solar cells 201 to 204, and front-rear connection regions 212, 213 that connect the front side and the rear side in terminal parts 231 to 238 of the solar cells 201 to 204. Though not particularly illustrated, the details that the connector member 210 includes a flexible base member and an adhesive layer in the cell coupling region 211 and the adhesive layer is bonded to positive electrodes at the light reception side of the solar cells are the same as those of the flexible base material 113 and the adhesive layer 114 (see FIG. 3) in the first embodiment.

In the embodiment, as shown in FIG. 8A, the four solar cells 201 to 204 respectively have two terminal parts 231 to 238. The positive electrodes and the negative electrodes of the solar cells 201 to 204 are respectively formed to the terminal parts 231 to 238. The positions of the terminal parts 231 to 238 are on both ends of circular arc shapes on the outer periphery of the respective solar cells 201 to 204. The solar cells 201 to 204 have the positive electrodes as the electrodes on the front side (light reception side) and negative electrodes as the electrodes on the rear side. The details of the positive electrodes, the negative electrodes, the power generation structure, the processing method, etc. of the solar cells are the same as those of the solar cells 101, 102 in the first embodiment.

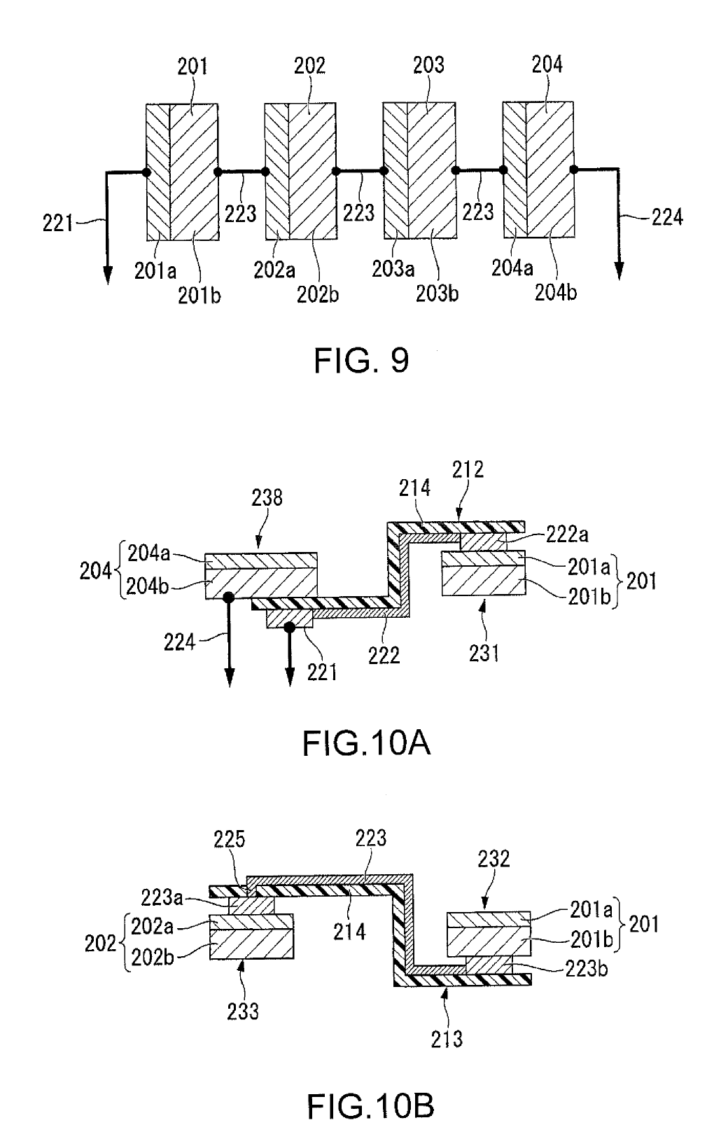

FIG. 9 shows a schematic circuit diagram of the solar cell module 200. The positive electrode 201a of the solar cell 201 is connected to a positive output terminal 221. The negative electrode 201b of the solar cell 201 is connected to the positive electrode 202a of the solar cell 202 via a wire 223. The negative electrode 202b of the solar cell 202 is connected to the positive electrode 203a of the solar cell 203 via the wire 223. The negative electrode 203b of the solar cell 203 is connected to the positive electrode 204a of the solar cell 204 via the wire 223. The negative electrode 204b of the solar cell 204 is connected to a negative output terminal 224. Thereby, the four solar cells 201 to 204 are series-connected between the positive output terminal 221 and the negative output terminal 224, and the output voltage may be increased.

In order to easily realize the series connection shown in FIG. 9, in the solar cell module 200 shown in FIG. 8B, the connector member 210 having the front-rear connection regions 212, 213 is used. These front-rear connection regions 212, 213 have flexible base materials 214 (see FIGS. 10A and 10B) continuing from the cell coupling region 211, and connect the rear sides and the front sides of the solar cells 201 to 204 between adjacent two terminal parts like the front-rear connection region 112 in the first embodiment. The front-rear connection regions 212, 213 are flexible because of the flexible base materials 214, and easily passed through between the two terminal parts.

Wires 222, 223 are formed on the front surface or the rear surface of the flexible base materials 214 in the front-rear connection regions 212, 213. Anisotropic conductive adhesive layers (not shown) are stacked on wiring layers forming the wires 222, 223. The details of the wiring layers and the anisotropic conductive adhesive layers are the same as the wiring layer 115 and the anisotropic conductive adhesive layer 116 (see FIG. 3) in the first embodiment.

There are four of the front-rear connection regions 212, 213 in total. As shown in FIG. 10A, one of them is an end part front-rear connection region 212 provided between the two solar cells on both ends of the series connection. As shown in FIG. 10B, the other three are intermediate part front-rear connection regions between the two solar cells located in the intermediate parts of the series connection.

In the end part front-rear connection region 212, a first end with the electrode on the front side (positive electrode 201a) as output is the solar cell 201, and a second end with the electrode on the rear side (negative electrode 204b) as output is the solar cell 204. As shown in FIG. 8B, the end part front-rear connection region 212 connects the front side in the terminal part 231 of the solar cell 201 and the rear side in the terminal part 238 of the solar cell 204. As shown in FIG. 10B, the positive output terminal 221 is provided in the terminal part 238 on the negative electrode 204b side of the solar cell 204. The positive output terminal 221 is electrically insulated from the negative electrode 204b side of the solar cell 204 through intervention of the flexible base material 214.

On the rear side of the flexible base material 214 of the end part front-rear connection region 212, the wire 222 is formed. A terminal 222a connected to the positive electrode 201a of the solar cell 201 is formed on the end of the wire 222. As a result, the positive electrode 201a of the solar cell 201 is connected to the positive output terminal 221 via the terminal 222a and the wire 222. On the negative electrode 204b side of the solar cell 204, the negative output terminal 224 connected to the negative electrode 204b is provided. The positive output terminal 221 and the negative output terminal 224 are provided on the rear side of the solar cell 204, and thereby, terminals for extracting the generated power may be provided on the rear side of the solar cell module 200.

As shown in FIG. 8B, the intermediate part front-rear connection regions 213 are provided in three locations of a first series-connection part that connects the negative electrode 201b in the terminal part 232 of the solar cell 201 and the positive electrode 202a in the terminal part 233 of the solar cell 202, a second series-connection part that connects the negative electrode 202b in the terminal part 234 of the solar cell 202 and the positive electrode 203a in the terminal part 235 of the solar cell 203, and a third series-connection part that connects the negative electrode 203b in the terminal part 236 of the solar cell 203 and the positive electrode 204a in the terminal part 237 of the solar cell 204. The three series-connection parts may have the same structure.

As a representative of the three series-connection parts, the sectional structure in the first series-connection part is shown in FIG. 10B. In the terminal part 232 at the solar cell 201 side, the terminal 223b on the negative electrode 201b of the solar cell 201 is connected to the wire 223. In the terminal part 233 at the solar cell 202 side, the terminal 223a on the positive electrode 202a of the solar cell 202 is connected to the wire 223. The wire 223 that series-connects the solar cells 201, 202 and the terminals 223a, 223b on both ends may be formed as a wiring layer on the front side of the flexible base material 214 in the intermediate part front-rear connection region 213. The terminal 223b is located on the front side of the flexible base material 214 and the terminal 223a is located on the rear side of the flexible base material 214, and thereby, the wire 223 passes a through hole 225 penetrating the flexible base material 214.

As described above, when the wires are formed as the wiring layer on the front surface or the rear surface of the connector member, the wires are integrated with the flexible base material. Thereby, an operation of individually positioning the wires becomes unnecessary and they may be positioned only by aligning predetermined locations of the front-rear connection regions with the positions of the electrodes. It is preferable that the flexible base materials are transparent because the positions of the wires may be visually aligned with the positions of the electrodes. The details of the positive output terminal 221, the wires 222, 223, the negative output terminal 224, and the through hole 225 are the same as those of the positive output terminal 121, the wires 122, 123, the negative output terminal 124, and the through hole 125 (see FIG. 5A) in the first embodiment.

It is preferable that the assembly procedure of the solar cell module 200 is as follows: the cell coupling region 211 is bonded to a part inner than the outer peripheral part of the nearly circular shape of the solar cells 201 to 204, and then, the front-rear connection regions 212, 213 are bonded to the terminal parts 231 to 238 and the connecting operation between the electrodes and the wires is performed. The connector member 210 has flexibility as a whole, accordingly, the degree of bending of the flexible base materials 214 is changed at the positioning of the electrodes and the wires, and thereby, displacement may be absorbed by the flexible base material 214.

The terminal parts 231 to 238 project from the outer peripheral part of the nearly circular shape of the solar cells 201 to 204, and bonding of the terminal parts 231 to 238 to the front-rear connection regions 212, 213 is easy. The connector member 210 may be bonded using pressure sensitivity, and thereby, may be bonded and fixed at the room temperature after positioning with sufficient accuracy by hand. The solar cells 201 to 204 are integrated by the connector member 210, and thereby, both alignment and temporary fixation may be performed even by hand and operability is improved. Further, the electrodes of the solar cells and the wires are bonded by thermal compression using a thermal compression unit and the anisotropic conductive adhesive is conducted, and thereby, fixation becomes more reliable. The solar cells 201 to 204 may be positioned with each other only by alignment and attachment of the connector member 210, and thus, the complex temporal fixation step may be omitted and the electrodes and the wires may be directly bonded by thermal compression.

A method of assembling the solar cell module 200 of the embodiment in a solar clock is not particularly limited, however, the method using the movement unit 130 and the pressing ring 140 (see FIG. 7) explained in the first embodiment may be employed.

In the second embodiment, the case where the four solar cells are series-connected is described, and it is confirmed that two to ten solar cells may be similarly series-connected and provided.

Further, one solar cell may be attached to the adhesive layer formed on one side of the flexible base material without series connection. In this case, the front-rear connection region provided as a part of the flexible base material connects the front side of the solar cell and the rear side of the solar cell, the positive output terminal provided on the rear side of the solar cell is electrically insulated from the negative electrode of the solar cell through intervention of the flexible base material, and the wire that electrically connects the positive electrode of the solar cell and the positive output terminal is provided in the front-rear connection region.

As above, the invention is explained based on the preferred embodiments, however, the invention is not limited to the above described embodiments, but various modification may be made without departing from the scope of the invention.

The shape of the solar cell module may be nearly the same shape or a nearly similarity shape with the face or not. The other shapes than the circular shape include polygonal shapes such as an octagonal shape or a square shape, polygonal shapes with rounded corners, oval shapes, or the like. The shapes of the solar cells may be any of shapes formed by dividing the shape of the solar cell module generally into a plurality of shapes.

In the connector member, the adhesive layer may be bonded to the opposite side to the light reception side of the solar cell (e.g., the negative electrode). When the location of the connector member is not at the light reception side of the solar cell, the connector member (flexible base material, adhesive layer) may be opaque. Separate connector members may be bonded to both sides of the solar cell.

Regarding the second embodiment, in FIG. 10A, the positive output terminal 221 is provided in the same terminal part 238 with the negative output terminal 224, however, they may be provided in different terminal parts. For example, only the negative output terminal 224 may be provided in the terminal part 238 of the solar cell 204, another terminal part (not shown) may be provided closer to the terminal part 231 in the solar cell 201, and the positive output terminal may be provided on the rear side of the terminal part via the flexible base material. Or, instead of providing the negative output terminal in the terminal part 238, the negative output terminal may be provided in another terminal part of the solar cell 204. Or, only the negative output terminal 224 may be provided in the terminal part 238 of the solar cell 204, the flexible base material may be folded back around the terminal part 231 in the solar cell 201, and the positive output terminal may be provided on the rear side of the terminal part 231 via the flexible base material. The wiring layer may be provided on an appropriate surface of the flexible base material and guided to the opposite surface via a through hole as appropriate.

What is claimed is:

1. A solar clock comprising:
a planar connector member using a flexible base material;
a plurality of solar cells bonded to the connector member; and
a wire formed on one or both of a front surface and a rear surface of the connector member and electrically connecting the plurality of solar cells.

2. The solar clock according to claim 1, wherein the flexible base material has transparency, and
light reception sides of the respective plurality of solar cells are bonded to the connector member.

3. The solar clock according to claim 1, wherein the respective plurality of solar cells are series-connected by a plurality of the wires.

4. The solar clock according to claim 1, wherein the connector member has an intermediate part front-rear connection region, and
in a first solar cell of the plurality of solar cells and a second solar cell electrically series-connected to the first solar cell, the wire provided in the intermediate part front-rear connection region electrically connects a rear side in the first solar cell and a front side of a second solar cell.

5. The solar clock according to claim 2, wherein the connector member has an end part front-rear connection region,
the wire provided in the end part front-rear connection region has one end electrically connected to one solar cell of the plurality of solar cells and the other end connected to a terminal, and
with the light reception side as a front surface, the terminal is provided on a rear side of the plurality of solar cells.

6. The solar clock according to claim 1, wherein an anisotropic conductive adhesive agent is used for bonding of the connector member and the plurality of solar cells.

7. A method of connecting solar cells comprising:
preparing a connector member having an adhesive layer formed on one side of a flexible base material and a wire formed on one or both of a front surface and a rear surface of the flexible base material;
positioning and bonding a plurality of solar cells to the adhesive layer; and
electrically connecting the plurality of solar cells by thermal compression bonding via the wire in parts in which electrical connection is necessary.
